(19) United States
(12) Patent Application Publication
(10) Pub. No.: US 2004/0032271 A1
(43) Pub. Date: Feb. 19, 2004

(54) Anisotropic probing contactor

(76) Inventors: Jeffrey E. Blackwood, Portland, OR (US); Tracy Myers, Clackamas, OR (US)

Correspondence Address: LSI LOGIC CORPORATION, 1621 BARBER LANE, MS: D-106 LEGAL, MILPITAS, CA, 95035, US

(21) Appl. No.: 10/223,412

(22) Filed: Aug. 19, 2002

(51) Int. Cl. G01R 31/02

(52) U.S. Cl. 324/754

(57) ABSTRACT

A contactor for providing electrical connections between a device under test and a tester input board. The device under test has first electrical contacts with a first pitch and a first diameter that contact a first side of the contactor, and the tester input board has second electrical contacts with a second pitch and a second diameter that contact a second side of the contactor. The contactor has a sheet of an electrically insulating material with a first surface at the first side of the contactor and a second surface at the second side of the contactor. The first surface and the second surface of the electrically insulating material are substantially parallel one to another. Electrical connectors extend along a length from the first side of the contactor to the second side of the contactor. The electrical connectors are substantially parallel one to another along their lengths. The electrical connectors have a third diameter that is no greater than the first pitch and the second pitch, and also have a third pitch that is no greater than the first pitch and the second pitch.

### FIELD

This invention relates to the field of integrated circuit fabrication. More particularly, this invention relates to electrical testing of integrated circuits.

### BACKGROUND

Integrated circuits are becoming increasingly smaller in size, while at the same time becoming increasingly complex and capable. These factors tend to create a variety of new problems that are encountered during the fabrication and testing processes. For example, whereas in the past an integrated circuit may have had dozens of electrical connections, many integrated circuits now have electrical connections that number in the hundreds. Further, this increased number of electrical connections are to be made within a surface area of the integrated circuit sometimes a fraction of the size of older integrated circuit designs. Thus, there is a need for a continual improvement in the methods and equipment that are used to fabricate and test integrated circuits.

As a more detailed example, it is desirable to electrically test integrated circuits in many ways and at many different points during fabrication. One point at which it is typically desired to electrically test an integrated circuit is after the front end processing is completed, at a test that is commonly referred to as wafer sort. At wafer sort, the integrated circuits are still united on a common substrate, such as a substrate of silicon, germanium, gallium arsenide, or some other III-V or otherwise semiconducting compound. In the case of flip chip integrated circuits, the integrated circuits typically will have already had solder bumps placed on their contacts as electrical interfaces.

The individual integrated circuits on a substrate are typically tested by aligning a specialized probe card to the electrical contacts, such as the solder bumps. The probe card makes electrical connections with the electrical contacts of the integrated circuits on the substrate on one side of the probe card, and makes electrical connections with a tester input board on the other side of the probe card. The tester input board is then electrically connected to the sensing and analysis electronics of a test station, by which the integrated circuits are electrically tested.

Because of the small size of the electrical contacts on an integrated circuit, and the small dimensional pitch between adjacent electrical contacts on an integrated circuit, the probe card must be very carefully constructed with a high degree of precision, so that proper electrical connections are made to each desired one of the electrical contacts on the integrated circuit, so that electrical shorting does not occur during the probing operation, such as by one of the probing elements on the probe care contacting more than one of the electrical contacts on the integrated circuit. This same degree of care is required to ensure that all of the electrical contacts to be tested are properly connected and not left as open circuits.

For this reason, probe cards tend to be specific to an individual integrated circuit design, and many different probe cards are typically required for the different integrated circuit designs that most companies produce. As the probe cards must be constructed with a relatively high degree of precision to reliably fulfill their intended purpose, probe cards tend to cost tens of thousands of dollars. Thus, an integrated circuit manufacturer tends to have a great amount of money invested in probe cards. Further, the use of the probe cards tends to require a certain amount of skill and effort to ensure that the probe card is properly aligned to the integrated circuits to be tested. Thus, the use of probe cards also tends to add to the processing costs of fabricating an integrated circuit, by requiring a relatively large amount of set up time.

What is needed, therefore, is a system by which electrical connections between devices under test, such as flip chip integrated circuits, ball bond integrated circuits, and packaged integrated circuits, and the tester input board of a tester can be made in a manner that is more reliable, which requires less set up time, which is not device specific, and which is less expensive than a probe card.

### SUMMARY

The above and other needs are met by a contactor for providing electrical connections between a device under test and a tester input board. The device under test has first electrical contacts with a first pitch and a first diameter that contact a first side of the contactor, and the tester input board has second electrical contacts with a second pitch and a second diameter that contact a second side of the contactor. The contactor has a sheet of an electrically insulating material with a first surface at the first side of the contactor and a second surface at the second side of the contactor. The first surface and the second surface of the electrically insulating material are substantially parallel one to another. Electrical connectors extend along a length from the first side of the contactor to the second side of the contactor. The electrical connectors are substantially parallel one to another along their lengths. The electrical connectors have a third diameter that is no greater than the first pitch and the second pitch, and also have a third pitch that is no greater than the first pitch and the second pitch.

In this manner, one or more of the electrical connectors in the contactor will align with both a given first electrical contact on the device under test and its associated second electrical contact on the tester input board. Because the diameter of the electrical connectors are no greater than the pitches of the electrical contacts on both the device under test and the tester input, and because the electrical connectors are substantially parallel one to another, the electrical connectors do not short out one electrical contact to another adjacent electrical contact. Further, because the diameter of the electrical connectors is no greater than the pitches of the electrical contacts on both the device under test and the tester input, there is at least one electrical connector for each of the associated pairs of electrical contacts on the device under test and the tester input. Thus, alignment of the contactor between the device under test and the tester input is easily accomplished and less critical.

In various preferred embodiments, the sheet of electrically insulating material comprises an elastomeric material, and the electrical connectors extend from the first side of the contactor to the second side of the contactor at a substantially perpendicular orientation to the first side of the contactor and the second side of the contactor. Most preferably, the electrical connectors comprise a metal, and in one embodiment extend past the first surface of the sheet of electrically insulating material.

Preferably, the third diameter of the electrical connectors is smaller than both the first diameter of the first electrical contacts and the second diameter of the second electrical contacts. Further, the third diameter of the electrical connectors in a further embodiment is smaller than both the first pitch of the first electrical contacts and the second pitch of the second electrical contacts. Further still, the third pitch of the electrical connectors is in yet another embodiment smaller than both the first diameter of the first electrical contacts and the second diameter of the second electrical contacts. Finally, the third pitch of the electrical connectors is in another embodiment smaller than both the first pitch of the first electrical contacts and the second pitch of the second electrical contacts.

The electrical connectors are preferably disposed within the sheet of electrically insulating material in a substantially uniform pattern. The device under test is, in alternate embodiments, a ball bond integrated circuit, a flip chip integrated circuit, and a packaged integrated circuit.

### BRIEF DESCRIPTION OF THE DRAWINGS

Further advantages of the invention are apparent by reference to the detailed description when considered in conjunction with the figures, which are not to scale so as to more clearly show the details, wherein like reference numbers indicate like elements throughout the several views, and wherein:

FIG. 1 is a cross sectional view of the contactor,

FIG. 2 is a top plan view of the contactor, and

FIG. 3 is cross sectional view of an alternate embodiment of the contactor.

### DETAILED DESCRIPTION

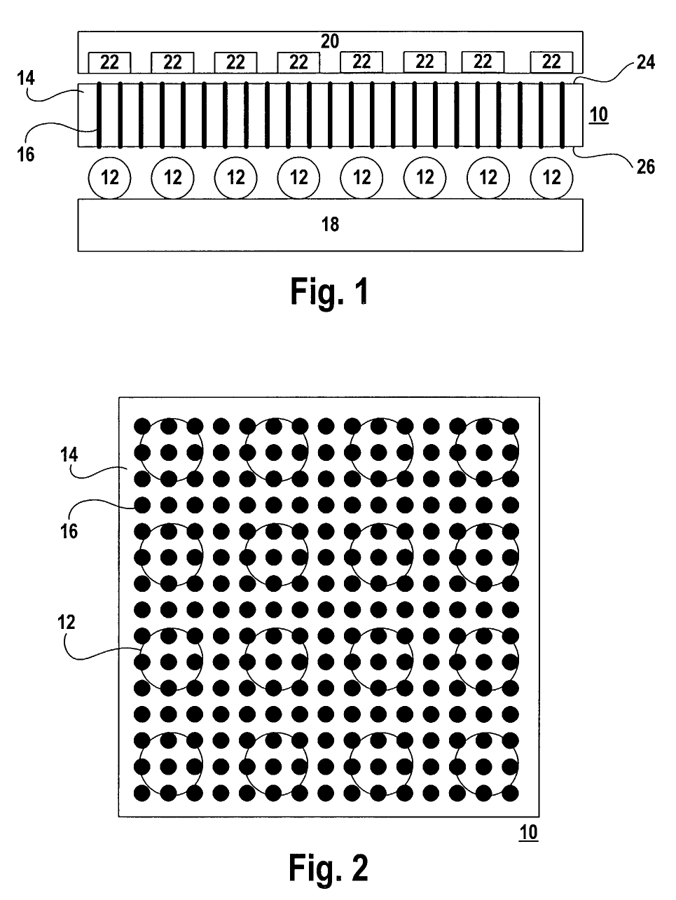

Referring now to FIG. 1 there is depicted a cross sectional view of the contactor 10. The contactor 10 is preferably formed of a flexible electrically insulating material 14, in which there are formed a plurality of substantially parallel electrical connectors 16, which extend from a first surface 26 on a first side of the contactor 10 to a second surface 24 on a second side of the contactor 10. Most preferably the electrical connectors 16 are disposed in a substantially perpendicular orientation with the surfaces 24 and 26 of the contactor 10. The insulating material 14 is most preferably an elastomeric material, and the electrical connectors 16 are most preferably formed of metal, and disposed in a uniform pattern.

The second surface 24 of the contactor 10 is preferably brought into contact with a tester input board 20 having electrical contacts 22, which make electrical connections with the electrical connectors 16. The first surface 26 of the contactor 10 is preferably brought into contact with a device under test 18, having electrical contacts 12. In the embodiment depicted in FIG. 1, the device under test 18 may be a flip chip integrated circuit 18 with solder bumps 12, or the device under test 18 may be a packaged integrated circuit 18 with solder balls 12. Of course, the scale of the elements in FIG. 1 would tend to be a bit larger in the case where a packaged integrated circuit 18 is depicted.

The diameter of the electrical connectors 16 is preferably no greater than the pitch between the electrical contacts 12 on the device under test 18 or the pitch between the electrical contacts 22 on the tester input board 20. In this manner, the alignment between the contactor 10 and the tester input board 20 and the device under test 18 is not critical, in that the contactor 10 can be disposed in virtually any horizontal position in which some of the electrical connectors 16 are available to make electrical connections with the electrical contacts 12 and 22, and no shorting between electrical contacts 12 and 22 occurs, and all of the electrical contacts 12 and 22 make proper electrical connection between associated pairs of contacts 12 and 22.

FIG. 2 depicts a top plan view of the contactor 10, showing the electrical connectors 16 in the electrically insulating material 14. Also representationally depicted are the electrical contacts 12 or 22, which are depicted as circles in FIG. 2. As depicted in FIG. 2, preferably the diameter and pitch of the electrical connectors 16 are much smaller than the diameter or pitch of either of the electrical contacts 12 or 22, so that a plurality of electrical connectors 16 make electrical connections between associated pairs of the contacts 12 and 22, and no electrical shorting takes place between the associated pairs. Further, by making the electrical connectors 16 small in this manner, the contactor 10 can be positioned almost randomly between the tester input board 20 and the device under test 18, and still make all the necessary and proper electrical connections between the two.

In this manner, a distinct, uniquely designed, and expensive probe card is not required for each design of the various devices under test, nor is there required a long set up and alignment time. Rather, the contactor 10 can be used with a wide variety of designs of the devices under test 18, because it is adaptable to provide electrical connections between a wide variety of diameters and pitches of electrical contacts. Thus, both the costs of inventory and set up time required for probe cards is dramatically reduced, and virtually eliminated.

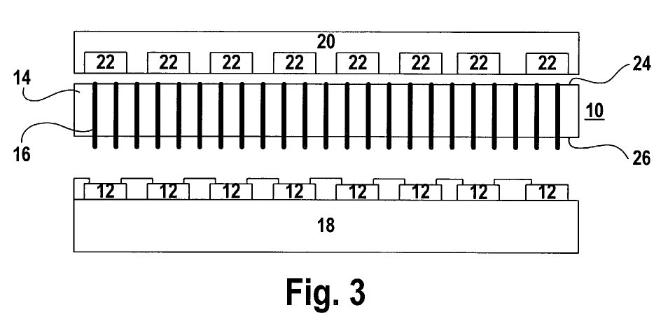

FIG. 3 depicts a contactor 10 where the electrical connectors extend beyond the first surface 26 to some extent. Such a configuration is preferably used such as when the device under test 18 is a ball bonded integrated circuit 18, having electrical contacts 12 that are somewhat recessed below the top most surface of an electrically insulating and protective material, such as depicted in FIG. 3.

The foregoing description of preferred embodiments for this invention have been presented for purposes of illustration and description. They are not intended to be exhaustive or to limit the invention to the precise form disclosed. Obvious modifications or variations are possible in light of the above teachings. The embodiments are chosen and described in an effort to provide the best illustrations of the principles of the invention and its practical application, and to thereby enable one of ordinary skill in the art to utilize the invention in various embodiments and with various modifications as is suited to the particular use contemplated. All such modifications and variations are within the scope of the invention as determined by the appended claims when interpreted in accordance with the breadth to which they are fairly, legally, and equitably entitled.

What is claimed is:

1. A contactor for providing electrical connections between a device under test having first electrical contacts with a first pitch and a first diameter that contact a first side of the contactor and a tester input board having second electrical contacts with a second pitch and a second diameter that contact a second side of the contactor, the contactor comprising:
a sheet of an electrically insulating material having a first surface at the first side of the contactor and a second surface at the second side of the contactor, where the first surface and the second surface are substantially parallel one to another, and
electrical connectors extending along a length from the first side of the contactor, to the second side of the contactor, the electrical connectors being substantially parallel one to another along their lengths, the electrical connectors having a third diameter that is no greater than the first pitch and the second pitch, and also having a third pitch that is no greater than the first pitch and the second pitch.

2. The contactor of claim 1, wherein the sheet of electrically insulating material comprises an elastomeric material.

3. The contactor of claim 1, wherein the electrical connectors extend from the first side of the contactor to the second side of the contactor at a substantially perpendicular orientation to the first side of the contactor and the second side of the contactor.

4. The contactor of claim 1, wherein the electrical connectors comprise a metal.

5. The contactor of claim 1, wherein the electrical connectors extend past the first surface of the sheet of electrically insulating material.

6. The contactor of claim 1, wherein the third diameter of the electrical connectors is smaller than both the first diameter of the first electrical contacts and the second diameter of the second electrical contacts.

7. The contactor of claim 1, wherein the third diameter of the electrical connectors is smaller than both the first pitch of the first electrical contacts and the second pitch of the second electrical contacts.

8. The contactor of claim 1, wherein the third pitch of the electrical connectors is smaller than both the first diameter of the first electrical contacts and the second diameter of the second electrical contacts.

9. The contactor of claim 1, wherein the third pitch of the electrical connectors is smaller than both the first pitch of the first electrical contacts and the second pitch of the second electrical contacts.

10. The contactor of claim 1, wherein the electrical connectors are disposed within the sheet of electrically insulating material in a substantially uniform pattern.

11. The contactor of claim 1, wherein the device under test is a ball bond integrated circuit.

12. The contactor of claim 1, wherein the device under test is a flip chip integrated circuit.

13. The contactor of claim 1, wherein the device under test is a packaged integrated circuit.

14. A contactor for providing electrical connections between a flip chip integrated circuit having first electrical contacts with a first pitch and a first diameter that contact a first side of the contactor and a tester input board having second electrical contacts with a second pitch and a second diameter that contact a second side of the contactor, the contactor comprising:
a sheet of an electrically insulating elastomeric material having a first surface at the first side of the contactor and a second surface at the second side of the contactor, where the first surface and the second surface are substantially parallel one to another, and
electrical connectors extending along a length from the first side of the contactor to the second side of the contactor, the electrical connectors being substantially parallel one to another along their lengths, the electrical connectors having a third diameter that is no greater than the first pitch and the second pitch, and also having a third pitch that is no greater than the first pitch and the second pitch.

15. The contactor of claim 14, wherein the electrical connectors extend from the first side of the contactor to the second side of the contactor at a substantially perpendicular orientation to the first side of the contactor and the second side of the contactor.

16. The contactor of claim 14, wherein both the third diameter and the third pitch of the electrical connectors is smaller than both the first diameter and first pitch of the first electrical contacts and both the second diameter and the second pitch of the second electrical contacts.

17. A contactor for providing electrical connections between a ball bond integrated circuit having first electrical contacts with a first pitch and a first diameter that contact a first side of the contactor and a tester input board having second electrical contacts with a second pitch and a second diameter that contact a second side of the contactor, the contactor comprising:
a sheet of an electrically insulating material having a first surface at the first side of the contactor and a second surface at the second side of the contactor, where the first surface and the second surface are substantially parallel one to another, and
electrical connectors extending along a length from the first side of the contactor to the second side of the contactor, the electrical connectors being substantially parallel one to another along their lengths, where the electrical connectors extend past the first side of the contactor, the electrical connectors having a third diameter that is no greater than the first pitch and the second pitch, and also having a third pitch that is no greater than the first pitch and the second pitch.

18. The contactor of claim 17, wherein the sheet of electrically insulating material comprises an elastomeric material.

19. The contactor of claim 17, wherein the electrical connectors extend from the first side of the contactor to the second side of the contactor at a substantially perpendicular orientation to the first side of the contactor and the second side of the contactor.

20. The contactor of claim 17, wherein both the third diameter and the third pitch of the electrical connectors is smaller than both the first diameter and first pitch of the first electrical contacts and both the second diameter and the second pitch of the second electrical contacts.
